(19) United States
(12) Patent Application Publication
(10) Pub. No.: US 2025/0015060 A1
(43) Pub. Date: Jan. 9, 2025

(54) ENHANCED COLOR GAMUT FOR ELECTRONIC DISPLAYS

(71) Applicant: Daktronics, Inc., Brookings, SD (US)

(72) Inventors: Shane Steven Carlson, Estelline, SD (US); Matthew Ray Mueller, Brookings, SD (US)

(21) Appl. No.: 18/764,959

(22) Filed: Jul. 5, 2024

Related U.S. Application Data
(60) Provisional application No. 63/512,516, filed on Jul. 7, 2023.

(51) Int. Cl. H01L 25/075

(52) U.S. Cl. CPC H01L 25/0753

(57) ABSTRACT

An electronic display comprises an array of pixels each comprising first, second, and third primary light-emitting elements that emit primary colors at first, second, and third physical primary color points on a chromaticity diagram, and one or more derivative light-emitting elements that each emit a derivative color at a derivative color point on the chromaticity diagram. The physical primary color points and each derivative color point are located on a boundary of a virtual color space that includes first, second, and third apexes at first, second, and third virtual primary color points on the chromaticity diagram. At least one of the first, second, and third virtual primary color points is different from the first, second, and third physical primary color points, respectively. A color gamut for the pixels is greater than a corresponding gamut for corresponding pixels that are configured to only emit the primary colors.

### CROSS-REFERENCE TO RELATED APPLICATION

This application claims the benefit of priority to U.S. Provisional Patent Application Ser. No. 63/512,516, filed on Jul. 7, 2023, entitled “ENHANCED COLOR GAMUT FOR ELECTRONIC DISPLAYS,” the disclosure of which is incorporated herein by reference in its entirety.

### BACKGROUND

Full color electronic information displays have many uses, such as dynamic billboards or scoreboards. Typically, these types of displays use pixels comprising a plurality of “primary” colored light-emitting elements that are combined in various combinations of intensity to produce a variety of colors beyond the primary colors themselves. The combined range of color that the display is capable of producing is typically referred to as the display's “color gamut,” or simply the “gamut.”

One of the most common primary color combinations used for light-emitting displays comprises a combination of red, green, and blue light-emitting elements, which is typically referred to as an “RGB display.” While RGB displays have a color gamut that includes a large percentage of naturally-occurring colors, the potential color gamut is still limited, with the full gamut available to the display being determined by the specific technology used for the light-emitting elements (with the most common being light-emitting diodes “LEDs”).

It has been found that if the display is included with at least one additional color source, the possible color gamut is increased. For example, in 2010, Sharp introduced its Quattron technology, which added an amber-colored subpixel to the conventional red, green, and blue subpixels to enhance the total color gamut.

### SUMMARY

The present disclosure describes an electronic display with a color gamut that is enhanced compared to the gamut available from a similarly-situated conventional RGB display. The electronic display comprises pixels that emit three or more primary colors of light, i.e., a first primary color (e.g., red), a second primary color (e.g., blue), and a third primary color (e.g., green). The pixels of the electronic display may also be configured to emit one or more additional colors of light (referred to herein as “derivative colors”) that may each vary from a corresponding primary color by a specified amount (e.g., a red derivative can vary slightly from the red primary, and/or a green derivative can vary slightly from the green primary, and/or a blue derivative can vary slightly from the blue primary). A set of theoretical or virtual primary colors are then determined that correspond to the first, second, and third primary colors, and to the one or more derivative colors. The virtual primary colors can then be used by content providers, which typically define color data in terms of what is to be displayed from a standard RGB pixel. In this way, the electronic display can provide for a color gamut that is larger than that which would be available with only the first, second, and third primary colors alone (e.g., by a conventional RGB display), but that does not complicate the content creation process beyond traditional three-primary color definition, such as RGB.

In an example described herein, an electronic display comprises an array of pixels of light-emitting elements, wherein each pixel comprises a first primary light-emitting element configured to emit a first primary color located at a first physical primary color point on a color space chromaticity diagram, a second primary light-emitting element configured to emit a second primary color located at a second physical primary color point on the color space chromaticity diagram, a third primary light-emitting element configured to emit a third primary color located at a third physical primary color point on the color space chromaticity diagram, and one or more derivative light-emitting elements each configured to emit a derivative color each located at a derivative color point on the color space chromaticity diagram. The first physical primary color point, the second physical primary color point, the third physical primary color point, and each derivative color point are located on a boundary of a virtual color space on the color space chromaticity diagram, wherein the boundary of the virtual color space comprises a first apex at a first virtual primary color point on the color space chromaticity diagram, a second apex at a second virtual primary color point on the color space chromaticity diagram, and a third apex at a third virtual primary color point on the color space chromaticity diagram. At least one of the first virtual primary color point, the second virtual primary color point, and the third virtual primary color point is different from the first physical primary color point, from the second physical primary color point, and from the third physical primary color point, respectively. A color gamut that can be produced by the array of pixels is greater than a corresponding gamut for corresponding pixels of corresponding light-emitting elements that are configured to only emit the first primary color, the second primary color, and the third primary color.

### BRIEF DESCRIPTION OF THE DRAWINGS

The drawings illustrate generally, by way of example, but not by way of limitation, various embodiments discussed in the present document.

FIG. 1 is a partial perspective view of an example display comprising a plurality of individual display modules that are operated in a cooperative manner to display information on the light-emitting display.

FIG. 2 is a perspective view of an example display module, which can be used as one of the display modules in the example display of FIG. 1.

FIG. 3 is a front view of a conventional RGB LED display, wherein each pixel comprises a red primary LED, a green primary LED, and a blue primary LED (“RGB primary LEDs”).

FIG. 4 is a non-color representation of the CIE 1931 XYZ chromaticity diagram overlaid with the color gamut that can be achieved by the conventional RGB LED display of FIG. 3.

FIG. 5 is a front view of an example LED display according to the present disclosure, wherein each pixel comprises the RGB primary LEDs and an additional derivative LED corresponding to each of the RGB primary LEDs.

FIG. 6 is a non-color representation of the CIE chromaticity diagram overlaid with the color gamut of the conventional RGB LED display of FIG. 3 and an enhanced color gamut of the gamut-enhanced LED display of FIG. 5.

FIG. 7 is a non-color representation of the CIE chromaticity diagram overlaid with the color gamut of the conventional RGB LED display of FIG. 3, the enhanced color gamut of the gamut-enhanced LED display of FIG. 5, and a virtual color space with a border drawn through the color points for each of the primary LEDs and each of the derivative LEDs of the gamut-enhanced LED display of FIG. 5 such that the apexes of the virtual color space comprise three virtual primary color points.

FIG. 8 is a front view of one pixel of another example LED display according to the present disclosure, wherein the pixel comprises the three RGB primary LEDs and a single derivative LED corresponding to one of the three primary LEDs.

FIG. 9 is a non-color representation of the CIE chromaticity diagram overlaid with the color gamut of the conventional RGB LED display of FIG. 3, the enhanced color gamut of the gamut-enhanced pixel of FIG. 8, and a virtual color space with a boundary drawn through the color points for each of the primary LEDs and through the color point for the single derivative LED of the pixel of FIG. 8 such that the apexes of the virtual color space comprise a virtual primary color point corresponding to the single derivative LED and two of the primary color points.

FIG. 10 is a front view of one pixel of another example LED display according to the present disclosure, wherein the pixel comprises the three RGB primary LEDs and two derivative LEDs corresponding to two of the three primary LEDs.

FIG. 11 is a non-color representation of the CIE chromaticity diagram overlaid with the color gamut of the conventional RGB LED display of FIG. 3, the enhanced color gamut of the gamut-enhanced pixel of FIG. 10, and a virtual color space drawn through the color points for each of the primary LEDs and through the two color points for the two derivative LEDs of the pixel of FIG. 10 such that the apexes of the virtual color space comprises two virtual primary color points corresponding to the two derivative LEDs and one of the primary color points.

### DETAILED DESCRIPTION

The following detailed description is of color electronic displays comprising an array of pixels each comprising a plurality of light-emitting elements, such as light-emitting diodes (LEDs). Each pixel comprises three or more “primary” colors and at least one “derivative” color. The display is configured to determine one or more “virtual” primary colors to provide a virtual pixel. The virtual pixel is used to control the display based on content data corresponding to the primary colors alone.

This detailed description includes references to the accompanying drawings, which form a part of the detailed description. The drawings show, by way of illustration, specific embodiments in which the invention may be practiced. These embodiments, which are also referred to herein as “examples,” are described in enough detail to enable those skilled in the art to practice the invention. The example embodiments may be combined, other embodiments may be utilized, or structural, and logical changes may be made without departing from the scope of the present invention. While the disclosed subject matter will be described in conjunction with the enumerated claims, it will be understood that the exemplified subject matter is not intended to limit the claims to the disclosed subject matter. The following detailed description is, therefore, not to be taken in a limiting sense, and the scope of the present invention is defined by the appended claims and their equivalents.

References in the specification to “one embodiment,” “an embodiment,” “an example embodiment,” etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1 to about 5” should be interpreted to include not only the explicitly recited values of about 0.1 to about 5, but also the individual values (e.g., 1, 2, 3, 4, etc.) and sub-ranges within the indicated range (e.g., 0.1 to 0.7, 1.2 to 2.38, 3.3 to 4.5, etc.) within the indicated range. The statement “about X to Y” has the same meaning as “about X to about Y,”” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. Unless indicated otherwise, the statement “at least one of” when referring to a listed group is used to mean one or any combination of two or more of the members of the group. For example, the statement “at least one of A, B, and C” can have the same meaning as “A; B; C; A and B; A and C; B and C; or A, B, and C,” or the statement “at least one of D, E, F, and G” can have the same meaning as “D; E; F; G; D and E; D and F; D and G; E and F; E and G: F and G; D, E, and F; D, E, and G; D, F, and G; E, F, and G; or D, E, F, and G.”

In the methods described herein, the steps can be carried out in any order without departing from the principles of the invention, except when a temporal or operational sequence is explicitly recited. Furthermore, specified steps can be carried out concurrently unless explicit language recites that they be carried out separately. For example, a recited act of doing X and a recited act of doing Y can be conducted simultaneously within a single operation, and the resulting process will fall within the literal scope of the process. Recitation in a claim to the effect that first a step is performed, and then several other steps are subsequently performed, shall be taken to mean that the first step is performed before any of the other steps, but the other steps can be performed in any suitable sequence, unless a sequence is further recited within the other steps. For example, claim elements that recite “Step A, Step B, Step C, Step D, and Step E” shall be construed to mean step A is carried out first, step E is carried out last, and steps B, C, and D can be carried out in any sequence between steps A and E (including with one or more steps being performed concurrent with step A or Step E), and that the sequence still falls within the literal scope of the claimed process. A given step or sub-set of steps can also be repeated.

Furthermore, specified steps can be carried out concurrently unless explicit claim language recites that they be carried out separately. For example, a claimed step of doing X and a claimed step of doing Y can be conducted simultaneously within a single operation, and the resulting process will fall within the literal scope of the claimed process.

The term “about” as used herein can allow for a degree of variability in a value or range, for example, within 10%, within 5%, within 1%, within 0.5%, within 0.1%, within 0.05%, within 0.01%, within 0.005%, or within 0.001% of a stated value or of a stated limit of a range, and includes the exact stated value or range.

The term “substantially” as used herein refers to a majority of, or mostly, such as at least about 50%, 60%, 70%, 80%, 90%, 95%, 96%, 97%, 98%, 99%, 99.5%, 99.9%, 99.99%, or at least about 99.999% or more, or 100%.

In addition, it is to be understood that the phraseology or terminology employed herein, and not otherwise defined, is for the purpose of description only and not of limitation. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference should be considered supplementary to that of this document; for irreconcilable inconsistencies, the usage in this document controls.

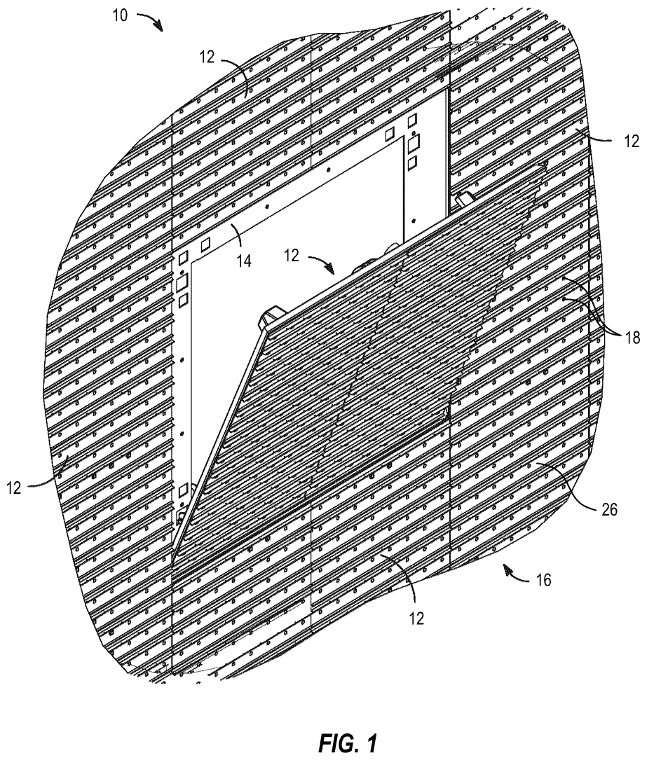

FIG. 1 is a perspective view of an example information display 10 (also referred to simply as “display 10”) that can include the color gamut enhancements described herein. The display 10 is configured to display one or more of video, graphical, or textual information. The display 10 includes one or more individual display modules 12 mounted to one or more supports, such as a support chassis 14. In examples wherein the display 10 is formed from a plurality of the display modules 12. The display modules 12 operate together so that the overall display 10 appears as a single, larger display. FIG. 1 shows one of the display modules 12 being in a pivoted or tilted position relative to the support chassis 14, which can occur when that display module 12 is in the process of being mounted to or dismounted from the support chassis 14. The other display modules 12 in the display 10 shown in FIG. 1 have already been mounted to the support chassis 14. The display 10 can include a display surface 16 configured to display the video, graphical, or textual information from the display 10. A plurality of light-emitting elements 18 is mounted to the display surface 16. For example, light-emitting elements 18 can be mounted to one or more module support structures on each of the display module 12, such as one or more of a circuit board, potting, or a module frame of a corresponding display module 12. The light-emitting elements 18 are operated together to display the video, graphical, or textual information on the display 10.

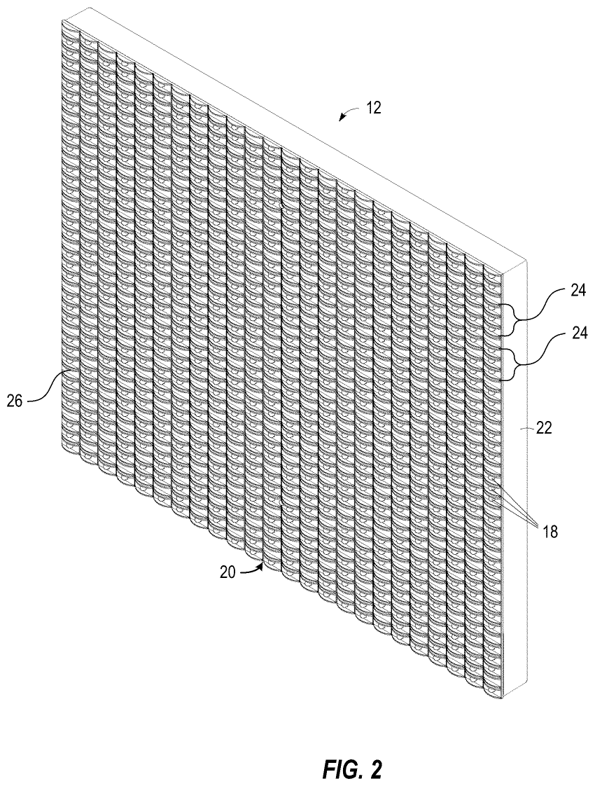

The light-emitting elements 18 can be any type of light-emitting technology known or yet to be discovered for the emission of light from a small area (e.g., from a pixel area), particularly light-emitting technology that is or can be used to display visual information, such as video, graphical, or textual information. At the time of filing of the present application, light-emitting diodes (LEDs) are one of the most common light-emitting technologies in use for large-scale video or graphical displays of the type described herein. As such, for the sake of brevity, the remainder of the present disclosure will refer to light-emitting elements that can be used in a display (including the light-emitting elements 18 shown in FIGS. 1 and 2) as LEDs. Those of skill in the art will appreciate, however, that any time the present disclosure uses the term “light-emitting diode” or “LED,” that light-emitting devices other than LEDs can be used, including, but not limited to, liquid crystal display devices (LCDs), organic light-emitting diodes (OLEDs), organic light-emitting transistors (OLETs), surface-conduction electron-emitter display devices (SEDs), field-emission display devices (FEDs), laser TV quantum dot liquid crystal display devices (QD-LCDs), quantum dot light-emitting diode display devices (QD-LEDs), ferro-liquid display devices (FLDs), and thick-film dielectric electroluminescent devices (TDELs).

FIG. 2 is a perspective view of an example display module 12 that can be used in the display 10 of FIG. 1. The display module 12 includes a front face 20 configured to provide for a display of graphics or video content. A plurality of the LEDs 18 is mounted to the front face 20 by being mounted onto a module support structure 22, which can include, for example, an electronics circuit board and a module frame. The LEDs 18 can be operated in such a way that the display module 12 will display a portion of the video, graphical, or textual information to be shown on the display 10. The front face 20 of the display module 12 is aligned and oriented relative to front faces 20 of one or more adjacently-positioned display modules 12 so that the front faces 20 combine and cooperatively form the overall display surface 16 of the full display 10 (shown in FIG. 1). The plurality of display modules 12 are operated together in such a way as to display the video, graphical, or textual information in a cohesive manner so that the entire display 10 appears to a viewer as a single display that is larger than the individual display modules 12.

The LEDs 18 are arranged into an array of pixels 24 (best seen in FIG. 2). Each pixel 24 includes a plurality of LEDs 18 grouped together in close proximity. Typically, a pixel 24 includes three (3) or more LEDs 18 per pixel 24. The proximity of the LEDSs 18 in each pixel 24 allows the pixel 24 to appear to a viewer of the display 10 as a single point in a two-dimensional array. Each individual pixel 24 can be operated to produce a specified light output (e.g., a specified color at a specified intensity) so that to the viewer, the display 10 appears to form recognizable shapes, such as letters or numbers to display textual information or recognizable shapes to display graphical or video information.

In a color display, the LEDs 18 include a plurality of different colored LEDs 18 and the various colors of the LEDs 18 for each pixel 24 can be cooperatively operated to display what appears to be a spectrum of different colors for the viewer of the display 10. In an example, each pixel 24 includes three or more colors that are selected to provide for a large gamut of colors that can be produced at each pixel 24 of the display 10. These colors are typically referred to as “primary colors,” and they can, when combined with different intensities, produce each color within the overall gamut. One of the most common combinations of primary colors for light-emitting displays such as the display 10 are red, green, and blue (also referred to as “RGB”). Therefore, in an example, each pixel 24 includes at least one red LED 18, at least one green LED 18, and at least one blue LED 18. The display 10 can also provide a black or empty looking surface over a portion of the display, when desired, by deactivating or turning off the LEDs 18 in a designated area of pixels 24.

As used herein, the term “red” refers to light with a range of wavelengths that a human viewer typically perceives as being red in color (typically from about 605 nanometers (nm) to about 630 nm); the term “green” refers to light with a range of wavelengths that a human viewer typically perceives as being green in color (typically from about 520 nm to about 550 nm); and the term “blue” refers to light with a range of wavelengths that a human viewer typically perceives as being blue in color (e.g., from about 460 nm to about 485 nm). In a non-limiting example that is common in commercial electronic displays, “red” LEDs emit light having a wavelength of from about 615 nm to about 620 nm, “green” LEDs emit light having a wavelength of from about 530 nm to about 535 nm, and “blue” LEDs emit light having a wavelength of from about 470 nm to about 475 nm.

Although FIGS. 1 and 2 show an example display with a plurality of display modules, the color-gamut enhancement of the present disclosure is not limited to use with a modular display. Rather, those having skill in the art will appreciate that other display configurations can be used without varying from the scope of the present invention, including a unitary display that is not broken up into individual modules.

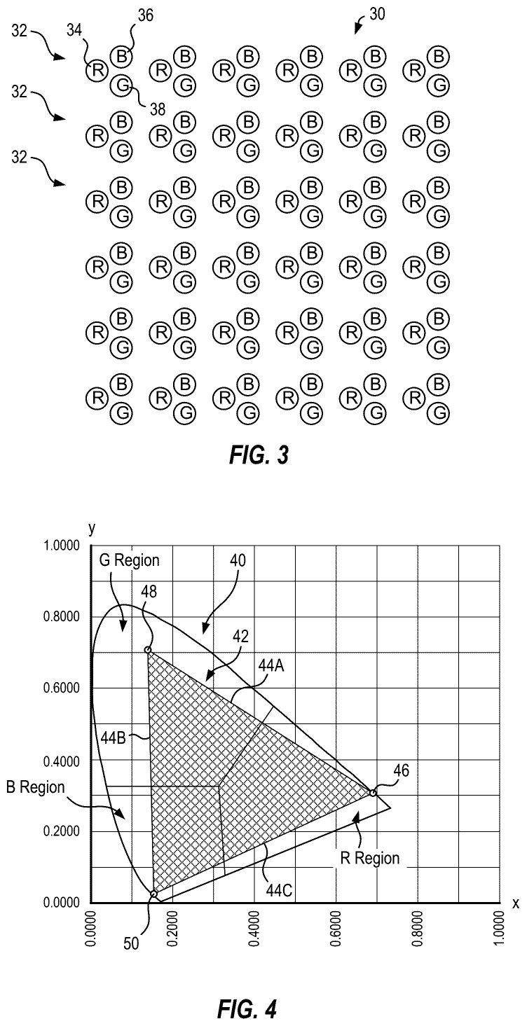

FIG. 3 shows a close-up view of an example array 30 of pixels 32 in a conventional RGB display. The conventional RGB configuration includes three LEDs in each pixel 32, one for each of the three primary colors, i.e., a red LED 34 (designated with the letter “R” in FIG. 3), a green LED 36 (designated with the letter “G”), and a blue LED 38 (designated by the letter “B”). The configuration of the pixels 32 shown in FIG. 3 could be used on the example display 10 and display module 12 of FIGS. 1 and 2. In an example that is common in commercially-available displays, the red LEDs 34 emit red light at a wavelength of from about 615 nanometers (“nm”) to about 620 nm, the green LEDs 36 emit green light at a wavelength of from about 530 nm to about 535 nm, and the blue LEDs 38 emit blue light at a wavelength of from about 470 nm to about 475 nm.

The physical configuration of the pixels 32 in the example array 30 a generally triangular configuration, e.g., with each LED 34, 36, 38 at the vertex of an equilateral triangle. However, those having skill in the art will appreciate that the displays of the present disclosure are not limited to the triangular configuration shown in FIG. 3 or to any other configuration, and that other specific layouts of the light-emitting elements in the pixels can be used including, but not limited to, a linear pixel (e.g., with each light-emitting element arranged generally or substantially along the same line, which can be vertical or substantially vertical as in the example of FIG. 2, horizontal or substantially horizontal, or diagonal), a non-equilateral triangle, or a non-regular geometric shape.

the center-to-center distance between LEDs in each pixel 32 (such as between the center of the red LED 34 and the green LED 36, between the green LED 36 and the blue LED 38, or between the blue LED 38 and the red LED 34) is small enough so that at the expected viewing distance, the individual LEDs 34, 36, 38 will be indistinguishable to the human eye such that the light emitted from the LEDs 34, 36, 38 in the pixel 32 will blend together and form a single color for that point in the pixel array 30. In a non-limiting example, the center-to-center distance between LEDs in each pixel 32 is 3 mm or less, such as 2.5 mm or less, 2 mm or less, 1.9 mm or less, 1.8 mm or less, 1.75 mm or less, 1.7 mm or less, 1.6 mm or less, 1.5 mm or less, 1.4 mm or less, 1.3 mm or less, 1.25 mm or less, 1.2 mm or less, 1.1 mm or less, 1 mm or less, 0.95 mm or less, 0.9 mm or less, 0.85 mm or less, 0.8 mm or less, 0.75 mm or less, 0.7 mm or less, 0.65 mm or less, 0.6 mm or less, 0.55 mm or less, 0.5 mm or less, 0.45 mm or less, 0.4 mm or less, 0.35 mm or less, 0.25 mm or less, 0.2 mm or less, 0.15 mm or less, or 0.1 mm or less.

FIG. 4 is a non-color version of an xy chromaticity diagram 40 adopted by the International Commission on Illumination (also known as “Commission Internationale de l'éclairage,” or “CIE”) in 1931, sometimes referred to as the “CIE 1931 XYZ chromaticity diagram” or the “CIE 1931 XYZ color space,” and which will be referred to hereinafter as “the CIE chromaticity diagram 40.” As will be appreciated with those of skill in the art who are familiar with the CIE chromaticity diagram 40, it is a conceptual representation of the portion of the light spectrum that is visible to humans. For reason that are not necessary to describe herein, it was decided to depict the CIE chromaticity diagram 40 with the rounded triangular shape shown in FIG. 4. The rounded triangle shape includes three regions at the “corners” of the rounded triangle corresponding to three primary light colors, i.e., red light (labeled as the “R REGION” in FIG. 4), green light (labeled as the “G REGION” in FIG. 4), and blue light (labeled as the “B REGION” in FIG. 4), with the three primary color regions being divided by black lines (which do not typically appear in full-color representations of the CIE chromaticity diagram 40). As will be understood by those having skill in the art, each location on the CIE chromaticity diagram 40 corresponds to a different color, e.g., a specific hue and saturation, which are used to determined x and y coordinates on the CIE chromaticity diagram 40. Therefore, each location on the CIE chromaticity diagram 40 may also be referred to herein as a “color” or a “color point.”

The CIE chromaticity diagram 40 shown in FIG. 4 is overlaid by a conceptual representation of the color gamut 42 that is achievable by a conventional RGB display, such as one using the array 30 of LED pixels 32 shown in FIG. 3. In an example, the color gamut 42 is bounded by a triangular boundary in FIG. 4, which is determined based on the primary colors emitted by the LEDs 34, 36, 38; i.e., a red primary color point 46, which corresponds to the color of light emitted by the red primary LED 34, a green primary color point 48, which corresponds to the color of light emitted by the green primary LED 36, and a blue primary color point 50, which corresponds to the color of light emitted by the blue primary LED 38. Because the primary color points 46, 48, 50 correspond to the actual colors of light emitted by the physically existing LEDs 34, 36, 38, they will also be referred to herein as “physical primary color points 46, 48, 50,” to distinguish them from the “virtual primary color points 94, 96, 98,” which are described in detail below.

In the example shown in FIG. 4, the boundary of the color gamut 42 is formed by drawing a boundary line between each pair of the physical primary color points 46, 48, 50—e.g., a first boundary line 44A between the red physical primary color point 46 and the green physical primary color point 48, a second boundary line 44B between the green physical primary color point 48 and the blue physical primary color point 50, and a third boundary line 44C between the blue physical primary color point 50 and the red physical primary color point 46.

The present disclosure describes an electronic display with a color gamut that is enhanced compared to the gamut available from conventional RGB displays, such as the color gamut 42 for the conventional RGB array 30. In order to provide the enhanced color gamut, electronic displays according to the present disclosure comprise pixels that a plurality of primary colors of light. In most cases, each pixel will include three (3) primary colors, such as conventional red, green, and blue. For example, the display pixels emit a first primary color located at a first point on the CIE chromaticity diagram 40 (e.g., the red LED 34 emitting red light at the red physical primary color point 46 on the CIE chromaticity diagram 40), a second primary color located at a second point on the CIE chromaticity diagram 40 (e.g., the green LED 36 emitting green light at the green physical primary color point 48 on the CIE chromaticity diagram 40), and a third primary color located at a third point on the CIE chromaticity diagram 40 (e.g., the blue LED 38 emitting blue light at the blue physical primary color point 50 on the CIE chromaticity diagram 40).

The pixels of the electronic display are also configured to emit one or more additional colors of light, also referred to as “derivative colors” for one, two, or all three of the primary colors. In an example, each derivative color is proximate in color to a corresponding one of the primary colors. Specifically, each derivative color is located on the CIE chromaticity diagram 40 proximate to the location of its corresponding primary color. As used herein, the term “proximate” when referring to the location of primary and derivative colors on the CIE chromaticity diagram 40, can include a derivative color being in the same color region of the chromaticity diagram 40. For example, a red derivative color can be considered to be located proximate to the red physical primary color point 46 when both points are in the R REGION of the CIE chromaticity diagram, a green derivative color can be considered to be located proximate to the green physical primary color point 48 when both points are in the G REGION of the CIE chromaticity diagram 40, and a blue derivative color can be considered to be located proximate to the blue physical primary color point 50 when both color points are in the B REGION of the CIE chromaticity diagram 40. In another example, the term “proximate” can mean being within a specified distance on the CIE chromaticity diagram 40, e.g., such as no more than 0.02 (according to the units on the x and y axes of the CIE chromaticity diagram 40) away from its corresponding physical primary color point, for example no more than about 0.01 away from the corresponding physical primary color point, such as no more than about 0.009, no more than about 0.008, no more than about 0.007, no more than about 0.006, or no more than about 0.005 away from the corresponding physical primary color point.

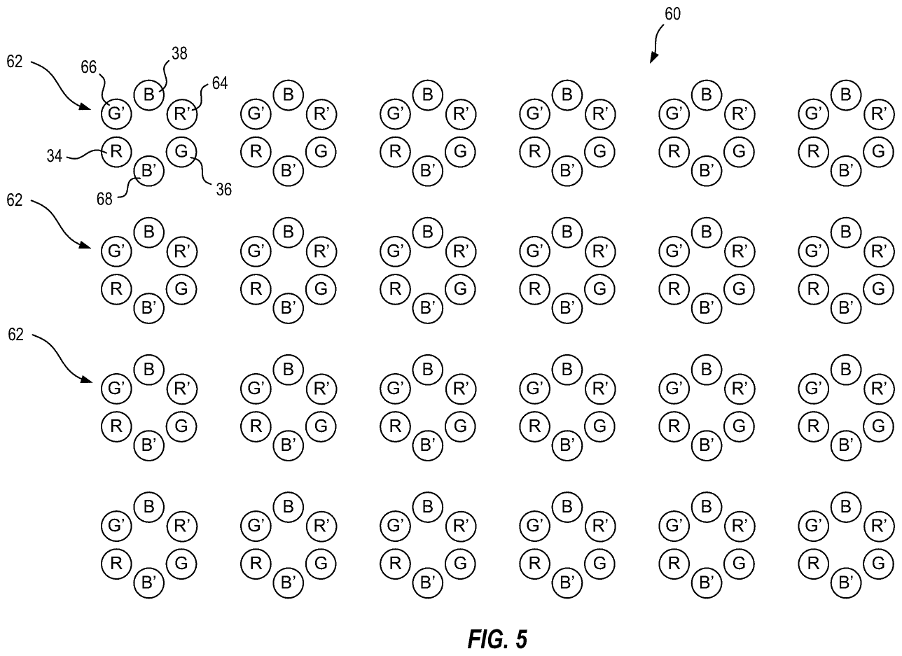

FIG. 5 shows an example of an array 60 of pixels 62 that each includes the three primary LEDs, e.g., a red primary LED 34, a green primary LED 36, and a blue primary LED 38 (which are given the same reference numbers as the LEDs 34, 36, 38 in the conventional RGB pixel 32 of FIG. 3 for the sake of consistency), and three derivative LEDs 64, 66, and 68 that each emit a color that is proximate (on the CIE chromaticity diagram 40) to the color emitted by a corresponding one of the primary LEDs 34, 36, 38. In the example shown in FIG. 5, the first derivative LED 64 corresponds to the red primary LED 34 (designated R′ (R prime), also referred to as the “red derivative LED 64”), the second derivative LED 66 corresponds to the green primary LED 36 (designated G′ (G prime), also referred to as the “green derivative LED 66”), and the third derivative LED 68 corresponds to the blue primary LED 38 (designated B′ (B prime), also referred to as the “blue derivative LED 68”).

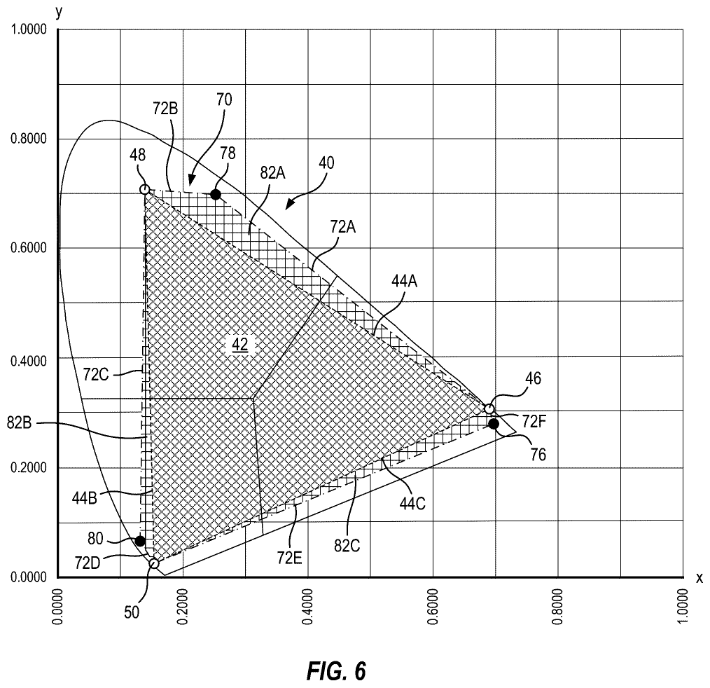

FIG. 6 shows a visual representation of a color gamut 70 that can be achieved by the array 60 of pixels 62 from FIG. 5 overlayed onto the CIE chromaticity diagram 40. Similar to the color gamut 40 for the conventional RGB pixels 32, the color gamut 70 is defined by boundary lines 72A, 72B, 72C, 72D, and 72E drawn between each pair of colors emitted by the LEDS 34, 36, 38, 64, 66, 68 of the pixels 62. Similar to the conventional RGB gamut 42, the color gamut 70 is determined by a red physical primary color point 46 emitted by the red primary LED 34 (which is the same or substantially the same as the red physical primary color point 46 in FIG. 4), a green physical primary color point 48 emitted by the green primary LED 36 (is the same or substantially the same as the green physical primary color point 48 in FIG. 4), and a blue physical primary color point 50 emitted by the blue primary LED 38 (which is the same or substantially the same as the blue physical primary color point 50 in FIG. 4). The color gamut 70 is further defined by a red derivative color point 76 (which corresponds to the color of light emitted by the red derivative LED 64), a green derivative color point 78 (which corresponds to the color of light emitted by the green derivative LED 66), and a blue derivative color point 80 (which corresponds to the color of light emitted by the blue derivative LED 68). The locations of the primary physical color points 46, 48, 50 and the derivative color points 76, 78, 80 result in an irregular hexagonal shape. In the example shown in FIG. 6, the color gamut 70 is defined by boundary lines 72 including: a first boundary line 72A between the red physical primary color point 46 and the green derivative color point 78; a second boundary line between the green derivative color point 78 and the green physical primary color point 48; a third boundary line 72C between the green physical primary color point 48 and the blue derivative color point 80; a fourth boundary line 72D between the blue derivative color point 80 and the blue physical primary color point 50; a fifth boundary line 72E between the blue physical primary color point 50 and the red derivative color point 76; and a sixth boundary line 72F between the red derivative color point 76 and the red physical primary color point 46.

As can be seen in FIG. 6, the color gamut 70 that is produced by the pixels 62 has a larger area than the corresponding color gamut 42 produced by the conventional RGB pixels 32 that only include the red primary LED 34, the green primary LED 36, and the blue primary LED 38. For example, the gamut 70 formed by the inclusion of the derivative LEDs 64, 66, 68 in addition to the primary LEDs 34, 36, 38 includes additional regions 82A, 82B, 82C beyond the original confines of the gamut 42 provided only by the primary LEDs 34, 36, 38.

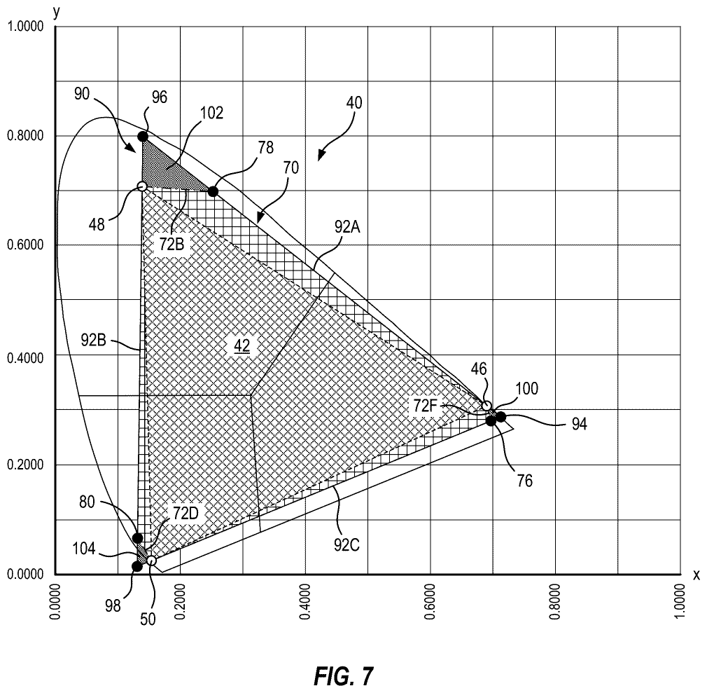

In an example, the derivative color points 76, 78, 80 emitted by the derivative LEDs 64, 66, 68 are each positioned on the CIE chromaticity diagram 40 relative to a corresponding one of the physical primary color points 46, 48, 50 emitted by the primary LEDs 34, 36, 38 so that a virtual color space can be drawn with a boundary that passes through all of the physical primary color points 46, 48, 50 and the derivative color points 76, 78, 80 on the CIE chromaticity diagram 40. As described in more detail below, the apexes of the boundary define “virtual color points” corresponding to the same primary colors (e.g., red, green, and blue), but at different points on the CIE chromaticity diagram 40 from the location of the physical primary color points 46, 48, 50 and the derivative color points 76, 78, 80. FIG. 7 shows a visual representation of a virtual color space 90 on the CIE chromaticity diagram 40 that was created by drawing virtual boundary lines 92A, 92B, 92C that pass through all of the color points 46, 48, 50, 76, 78, 80 from the color gamut 70, which results in apex points 94, 96, 98 of the virtual color space 90. In an example, the virtual color space is drawn so that the number of apex points is equal to the number or primary colors desired to define the colors of the display, such as three in the case of conventional RGB color definition, which results in a triangular virtual color space 90. Because each apex point 94, 96, 98 represent colors of light that are not actually emitted by any of the physical LEDs 34, 36, 38, 64, 66, 68, the apex points 94, 96, 98 will also be referred to as “virtual primary color points 94, 96, 98” to distinguish them from the physical primary color points 46, 48, 50 that are actually emitted from the primary LEDs 34, 36, 38. In the example shown in FIG. 7, a first apex point 94 is located in the R Region of the CIE chromaticity diagram 40 such that the first apex point 94 will also be referred to as “the red virtual primary color point 94, a second apex point 96 is located in the G Region such that the second apex point 96 will also be referred to as “the green virtual primary color point 94, and a third apex point 98 is located in the B Region such that the third apex point 98 will also be referred to as “the blue virtual primary color point 98.

In an example, shown in FIG. 7, each of the virtual boundary lines 92A, 92B, 92C that form the virtual color space 90 are drawn between one of the physical primary color points 46, 48, 50 and a corresponding one of the other derivative color points 76, 78, 80. For example, the virtual color space 90 shown in the example of FIG. 7 is bounded by first, second, and third virtual boundary lines 92A, 92B, and 92C, respectively. In the example shown in FIG. 7, the first virtual boundary line 92A extends between the red and green virtual primary color points 94 and 96, respectively, and passes through the red physical primary color point 46 (e.g., a first of the primary colors) and the green derivative color point 78 (e.g., a first of the derivative colors that corresponds to the red primary color, that is, either the green derivative color or the blue derivative color). The second virtual boundary line 92B extends between the green and blue virtual primary color points 96 and 98, respectfully, and passes through the green physical primary color point 48 (e.g., a second of the primary colors) and the blue derivative color point 80 (e.g., a second of the derivative colors that corresponds to the green primary color, that is, either the red derivative color or the green derivative color). The third virtual boundary line 92C extends between the blue and red virtual primary color points 98 and 94, respectively, and passes through the blue physical primary color point 50 (e.g., the third primary color) and the red derivative color point 76 (e.g., a third of the derivative colors that corresponds to the blue primary color, that is, either the green derivative color or the red derivative color). In that example, the red virtual primary color point 94 is located at the intersection of the first and third virtual boundary lines 94A and 94C, the green virtual primary color point 94 is located at the intersection of the first and second virtual boundary lines 94A and 94B, and the blue virtual primary color point 98 is located at the intersection of the second and third virtual boundary lines 92B and 92C. In other examples, not shown, the virtual boundary line between the red virtual primary color point 94 and the green virtual primary color point 94 could instead be drawn so that it passes through the red derivative color point and the green physical primary color point. Similarly, the virtual boundary line between the green virtual primary color point 94 and the blue virtual primary color point 98 could instead be drawn so that it passes through the green derivative color point and the blue physical primary color point and/or the virtual boundary line between the blue virtual primary color point 98 and the red virtual primary color point 94 could instead be drawn so that it passes through the blue derivative color point and the red physical primary color point. The specific combination of physical primary color point and derivative color point that each virtual boundary line passes through can depend on the specific colors chosen for the primary LEDs 34, 36, 38 and the derivative LEDs 64, 66, 68 and where they fall on the CIE chromaticity diagram 40.

The inventors have discovered that defining the virtual color space 90 with the three virtual primary color points 94, 96, 98 has many advantages over the same physical display (e.g., with the same primary LEDs 34, 36, 38 and the same derivative LEDs 64, 66, 68) but where the color space emitted by the display is defined by the actual physical color points 46, 48, 50 and derivative color points 76, 78, 80. For example, defining the virtual color space 90 as described herein can allow a display with additional derivative emitters (such as the pixels 62 with the six total emitters, e.g., the primary LEDs 34, 36, 38 and the derivative LEDs 64, 66, 68) to be used in order to provide for the enhanced color gamut 70, but that can still be controlled as though it were a conventional display formed from only the three conventional primary colors (e.g., a conventional RGB display such as with the array 30 of pixels 32 shown in FIG. 3). The benefit of this arrangement allows upstream content providers (e.g., the party or parties that generates and/or provide the text, images, or video that is to be shown on the display) to define the color to be displayed by each pixel as a function of only three primary color emitters, even though the actual pixels 62 of the display include more than three emitters, e.g., the red primary LED 34, the green primary LED 36, the blue primary LED 38, the red derivative LED 64, the green derivative LED 66, and the blue derivative LED 68. For example, the upstream content provider could define the color of each pixel 62 at a certain point in time based on a first specified intensity for a red primary color emitter, a second specified intensity for a green primary color emitter, and a third specified intensity for a blue primary color emitter. Thus, the upstream content provider can continue to use standard video processing techniques (e.g., saturation, contrast, hue, etc.), which are almost universally based on equations defined by a conventional RGB configuration. Similarly, other aspects of the system that controls the display may be set up using the same type of standard video processing techniques (based on conventional RGB configurations).

The processor or controller that is running the display can be programmed to use the specified intensities for the primary color emitters provided by the upstream content provider to define “virtual intensities” for each of the virtual primary color points 94, 96, 98 define a corresponding set of “virtual intensities” for each of the virtual primary color points 94, 96, 98 and then to convert the virtual intensities at the virtual primary color points 94, 96, 98 to actual intensities to be emitted by each of the physical emitters of each pixel 62 (e.g., the LEDs 34, 36, 38, 64, 66, 68). For example, the processor or controller can calculate the following, based on the virtual intensities for the virtual primary color points 94, 96, 98 (which are equal to the specified intensities for the three primary color emitters received from the upstream content provider): a first corresponding intensity for the red physical primary color point 46 being emitted by the red primary LED 34; a second corresponding intensity for the green physical primary color point 48 being emitted by the green primary LED 36; a third corresponding intensity for the blue physical primary color point 50 being emitted by the blue primary LED 38; a fourth corresponding intensity for the red derivative color point 76 being emitted by the red derivative LED 64; a fifth corresponding intensity for the green derivative color point 78 being emitted by the green derivative LED 66; and a sixth corresponding intensity for the blue derivative color point 80 emitted by the blue derivative LED 68.

In an example, the corresponding intensity for each primary LED 34, 36, 38 and each derivative LED 64, 66, 68 can be determined based on the specified intensity for the same primary color emitter provided by the upstream content provider. For example, the processor or controller can select a first corresponding intensity for the red primary LED 34 and a fourth corresponding intensity for the red derivative LED 64 that, when combined, will achieve the equivalent of the specified intensity for the red primary emitter provided by the upstream content provider. Similarly, the processor or controller can select a second corresponding intensity for the green primary LED 36 and a fifth corresponding intensity for the green derivative LED 66 that, when combined, will achieve the equivalent of the specified intensity for the green primary emitter provided by the upstream content provider and/or can select a third corresponding intensity for the blue primary LED 38 and a sixth corresponding intensity for the blue derivative LED 68 that, when combined, will achieve the equivalent of the specified intensity for the blue primary emitter provided by the upstream content provider. In other examples, the controller or process can be programmed to determine other combinations of the first, second, third, fourth, fifth, and sixth corresponding intensities for the LEDs 34, 36, 38, 64, 66, 68 at the physical primary color points 46, 48, 50 and the derivative color points 76, 78, 80 that will result in producing a color at the same location on the CIE chromaticity diagram 40 that would be achieved based on the combination of the specified intensities for the red, green, and blue emitters (provided by the upstream content provider) at the virtual primary color points 94, 96, 98. The methods of achieving a particular color location on the CIE chromaticity diagram 40 based on some combination of intensities of the physical emitters of the display and the specific color points that those emitters generate is well understood by those having skill in the art.

In other words, the upstream content provider does not have to worry or even know how many colors of emitters each pixel 62 of the display has, and can instead define its colors according to a conventional RGB arrangement, which has been a standard method of color definition for light-emitting displays for decades. Similarly, the operator of the display does not have to worry about compatibility between the components of its system that use standard video processing techniques based on conventional RGB configurations and the display having pixels 62 with the additional derivative LEDs 64, 66, 68. Thus, the defining of the virtual color space 90 by the virtual primary color points 94, 96, 98 can also allow a system with more than three emitter colors to be backward compatible with existing conventional three-primary display systems.

A disadvantage of defining the virtual color space 90 based on the virtual primary color points 94, 96, 98 is that the virtual color space 90 can have regions that are outside the color gamut 70 that is physically possible to be generated by the LEDs 34, 36, 38, 64, 66, 68. This results in color regions 100, 102, 104 located within the virtual color space 90 proximate to the virtual primary color points 94, 96, 98, of colors that the display is not able to physically produce (also referred to as “undisplayable color regions 100, 102, 104”). If, for example, an upstream content provider indicates that one of the pixels 62 should display a color in one of the undisplayable color regions 100, 102, 104, then that pixel 62 will not be capable of displaying the exact color designated by the upstream content provider. However, the inventors do not believe that this is a major drawback. First, this will only happen at the extreme ends of the virtual color space 90, e.g., when the designated color is very close to one of the virtual primary color points 94, 96, 98. Second, the size of the undisplayable color regions 100, 102, 104 is small relative to the total size of the enhanced color gamut 70, so the desire to display colors within one of the undisplayable color regions 100, 102, 104 will most likely be rare. Third, most, if not all, of the colors within the undisplayable color regions 100, 102, 104 are very saturated versions of red, green, or blue that do not occur in nature (e.g., they are outside of the so-called “Pointer's Gamut”), which makes it even less likely that a color in one of the undisplayable regions 100, 102, 104 will be designated by an upstream content provider.

Finally, even if an upstream content provider wishes to display a color in one of the undisplayable color regions 100, 102, 104, it is possible for the processor or controller to be programmed to extrapolate any color in one of the undisplayable color regions 90, 93, 94 to a point along the enhanced color gamut 70, and the difference between the color in the undisplayable color region 100, 102, 104 and the extrapolated color will be almost imperceptible to the human eye. For example, if an indicated color is located in the undisplayable color region 100 proximate to the red virtual primary color point 94, the processor or controller can be programmed to instead display one of: the color at the red physical primary color point 46 (e.g., 100% emission from the red primary LED 34); the color at the red derivative color point 76 (e.g., 100% emission from the red derivative LED 64); or a color along the boundary line 72F between the red physical primary color point 46 and the red derivative color point 76 that is closest to the specified red color (e.g., some combination of emission by both the red primary LED 34 and the red derivative LED 64). Similarly, if an indicated color is located in the undisplayable color region 102 proximate to the green virtual primary color point 94, the processor or controller can be programmed to instead display one of: the color at the green physical primary color point 48 (e.g., 100% emission from the green primary LED 36); the color at the green derivative color point 78 (e.g., 100% emission from the green derivative LED 66); a color along the boundary line 72B between the green physical primary color point 48 and the green derivative color point 78 that is closest to the specified green color (e.g., some combination of emission by both the green primary LED 36 and the green derivative LED 66). Finally, if the indicated color is located in the undisplayable color region 104 proximate to the blue virtual primary color point 98, the processor or controller can be programmed to instead display one of: the color at the blue physical primary color point 50 (e.g., 100% emission by the blue primary LED 38); the color at the blue derivative color point 80 (e.g., 100% emission by the blue derivative LED 68); or a color along the boundary line 72D between the blue physical primary color point 50 and the blue derivative color point 80 (e.g., some combination of emission by both the blue primary LED 38 and the blue derivative LED 68). Alternatively, each pixel can include one or more additional derivative LEDs corresponding to one or more of the primary colors (e.g., one or more additional red derivative LEDs in addition to the red derivative LED 64 located at different points proximate to the red physical primary color point 46), wherein the color point of the additional derivate LED can be located within the corresponding undisplayable color region 100, 102, 104 (e.g., an additional red derivative LED in addition to the red derivative LED 64 with a color point in the red undisplayable color region 100, and/or an additional green derivative LED in addition to the green derivative LED 66 with a color point in the green undisplayable color region 102, and/or an additional blue derivative LED in addition to the blue derivative LED 68 with a color point located in the blue undisplayable color region 104).

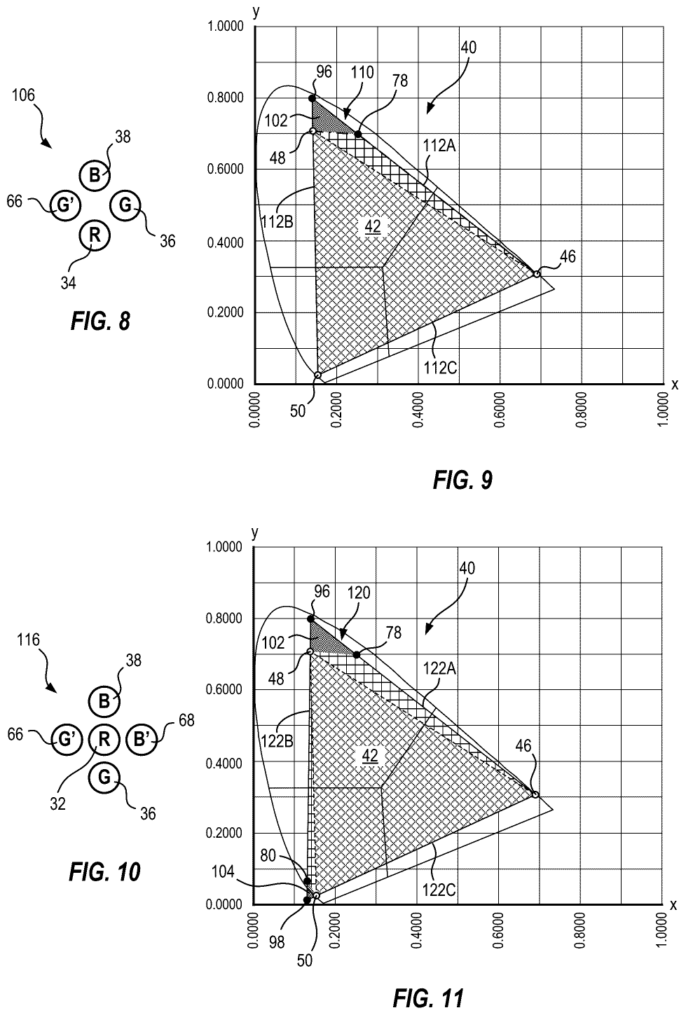

The example shown in FIG. 7 a virtual color space 90 formed based on pixels 62 that include a derivative emitter corresponding to each of all three of the primary emitters, in other words, the red derivative LED 64 corresponding to the red primary LED 34, the green derivative LED 66 corresponding to the green primary LED 36, and the blue derivative LED 68 corresponding to the blue primary LED 38. However, the virtual color space concept of the present disclosure is not limited to a display where there is a corresponding derivative emitter for each of the primary emitters. The same concept of generating a virtual color space that comprises three virtual primary color points can be applied if each pixel comprises a derivative emitter for only one of the three primary emitter colors or for only two of the three primary emitter colors. In such examples, the primary color point associated with each primary emitter that does not have a corresponding derivative emitter would act as the “virtual primary color point” for that primary color. FIGS. 8-11 demonstrate examples of this type of configuration.

FIG. 8 shows an example pixel 106 that includes only one derivative emitter, in this example only a green derivative LED 66, to go along with the three primary LEDs 34, 36, 38. FIG. 9 shows a visual representation of a virtual color space 110 that results from the example pixel 106 of FIG. 8. As can be seen in FIG. 9, there is only one “virtual” primary color point that is formed, i.e., the green virtual primary color point 94 because the pixel 106 includes only the green derivative LED 66. The other two apexes of the triangular virtual color space 100 are provided by the red physical primary color point 46 and the blue physical primary color point 50 (corresponding to the actual colors emitted by the red primary LED 34 and the blue primary LED 38, respectively). In the example of FIG. 9, the virtual color space 110 is bounded by a first virtual boundary line 112A between the red physical primary color point 46 (also acting as the red “virtual” primary color point for the virtual color space 110) and the green virtual primary color point 94 (wherein the first virtual boundary line 112A also passes through the green derivative color point 78), a second virtual boundary line 112B between the green virtual primary color point 94 and the blue physical primary color point 50 (also acting as the blue “virtual” primary color point for the virtual color space 110) (wherein the second virtual boundary line 112B also passes through the green physical primary color point 48), and a third virtual boundary line 112C between the blue physical primary color point 50 (also acting as the blue “virtual” primary color point for the virtual color space 110) and the red physical primary color point 46 (also acting as the red “virtual” color point for the virtual color space 110). Although the pixel 106 of FIG. 8 and the corresponding virtual color space 110 shown in FIG. 9 is for a configuration with the primary LEDs 34, 36, 38 and a green derivative LED 66, a person of skill in the art would be able to envision configurations where the green derivative LED 66 is replaced with only a red derivative LED or only a blue derivative LED without varying from the scope of the present disclosure.

FIG. 10 shows another example pixel 116 that includes two derivative color emitters in addition to the primary color LEDs 34, 36, 38. In this example, the two derivative color emitters are a green derivative LED 66 and a blue derivative LED 68. FIG. 11 shows a visual representation of the virtual color space 120 that results from the example pixel 116 of FIG. 10. As can be seen in FIG. 11, there are two “virtual” primary color points formed, i.e., the green virtual primary color point 94 (because the pixel 116 includes the green derivative LED 66) and the blue virtual primary color point 98 (because the pixel 116 includes the blue derivative LED 68). The third apex of the virtual color space 120 is provided by the red physical primary color point 46 (which corresponds to the actual color emitted by the red primary LED 34) acting as the red “virtual” primary color point. In the example of FIG. 11, the virtual color space 120 is bounded by a first virtual boundary line 122A between the red physical primary color point 46 (also acting as the red “virtual” primary color point for the virtual color space 120) and the green virtual primary color point 94 (wherein the first virtual boundary line 122A also passes through the green derivative color point 78), a second virtual boundary line 122B between the green virtual primary color point 94 and the blue virtual primary color point 98 (wherein the second virtual boundary line 122B also passes through the green physical primary color point 48 and the blue derivative color point 80), and a third virtual boundary line 122C between the blue virtual primary color point 98 and the red physical primary color point 46 (also acting as the red “virtual” primary color point for the virtual color space 120) (wherein the third virtual boundary line 122C also passes through the blue physical primary color point 50). Although the pixel 116 of FIG. 10 and the corresponding virtual color space 120 shown in FIG. 11 is for a configuration with the primary LEDs 34, 36, 38 along with a green derivative LED 66 and a blue derivative LED 68, a person of skill in the art would be able to envision configurations where the green derivative LED 66 is replaced with a red derivative LED (e.g., so that the two derivative emitters are a red derivative LED and a blue derivative LED) or where the blue derivative LED 68 is replaced with a red-gamut enhancing LED (e.g., so that the two derivative emitters are a red derivative LED and a green derivative LED) without varying from the scope of the present disclosure.

In both the example of FIGS. 8 and 9 and the example of FIGS. 10 and 11, as well as the example of FIGS. 5-7 discussed above, the pixels 62, 106, 116 of the display comprise more than the three primary color emitters (e.g., the pixel comprises one derivative color emitter corresponding to one of the primary color emitters, as in pixel 106, two derivative color emitters corresponding to two of the primary color emitters, as in pixel 116, or three derivative color emitters corresponding to all three of the primary color emitters, as in pixel 62), but because of the formation of the virtual color spaces 90, 110, 120, the colors to be emitted by the pixels 62, 106, 116 can be defined according to a three primary color system, as in conventional RGB displays. As discussed above, this allows an upstream content provider to designate colors to be displayed without having to worry about the actual physical configuration of the pixels that are being provided by the manufacturer of the display and without having to vary from the conventional method of defining the defining colors based on RGB colors. The processor or controller that controls the display can take the color information provided by the upstream content provider, with each color defined according to a conventional RGB rubric, and can convert the color information to a corresponding light output that is required for each of the physical emitters in the pixels 62, 106, 116 of the display.

In the case of the example of FIGS. 8 and 9, the “conversion” for the red and blue primary colors is very straightforward because the “virtual” red primary color point is the same as the red physical primary color point 46 emitted by the red primary LED 34 and the “virtual” blue primary color point is the same as the blue physical primary color point 50 emitted by the blue primary LED 38. Thus, the light output for the red primary LED 34 and the blue primary LED 38 is equal to the intensity values for the red and blue emitters provided by the upstream content provider. The only actual “conversion” required would be for the green virtual primary color point 96, which would involve the processor or controller converting the intensity provided for the green primary emitter provided by the upstream content provider to a combination of outputs for the green primary LED 36 and the green derivative LED 66 that would result in the specified green value. Similarly, in the example of FIGS. 10 and 11, the “conversion” for the red primary color is straightforward because the “virtual” red primary color point is the same as the red physical primary color point 46 emitted by the red primary LED 34. The processor or controller would only need to convert the intensity values for the green and blue primary emitters provided by the upstream content provider to corresponding output values for the green primary LED 36 and the green derivative LED 66 (for the specified intensity for the green primary emitter) and for the blue primary LED 38 and the blue derivative LED 68 (for the specified intensity from the blue primary emitter). The conversion for the pixel 62 that includes three derivative emitters, i.e., one for each primary color, is described above with respect to FIG. 7.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An electronic display comprising:
an array of pixels of light-emitting elements, wherein each pixel comprises a first primary light-emitting element configured to emit a first primary color located at a first physical primary color point on a color space chromaticity diagram, a second primary light-emitting element configured to emit a second primary color located at a second physical primary color point on the color space chromaticity diagram, a third primary light-emitting element configured to emit a third primary color located at a third physical primary color point on the color space chromaticity diagram, and one or more derivative light-emitting elements each configured to emit a derivative color each located at a derivative color point on the color space chromaticity diagram;
wherein the first physical primary color point, the second physical primary color point, the third physical primary color point, and each derivative color point are located on a boundary of a virtual color space on the color space chromaticity diagram, wherein the boundary of the virtual color space comprises a first apex at a first virtual primary color point on the color space chromaticity diagram, a second apex at a second virtual primary color point on the color space chromaticity diagram, and a third apex at a third virtual primary color point on the color space chromaticity diagram,
wherein at least one of the first virtual primary color point, the second virtual primary color point, and the third virtual primary color point is different from the first physical primary color point, from the second physical primary color point, and from the third physical primary color point, respectively;
wherein a color gamut that can be produced by the array of pixels is greater than a corresponding gamut for corresponding pixels of corresponding light-emitting elements that are configured to only emit the first primary color, the second primary color, and the third primary color.

2. The electronic display of claim 1, wherein each derivative color point is proximate to one of the first physical primary color point, the second physical primary color point, and the third physical primary color point on the color space chromaticity diagram.

3. The electronic display of claim 1, wherein the boundary of the virtual color space comprises a first virtual boundary line extending from the first virtual primary color point at the first apex to the second virtual primary color point at the second apex, a second virtual boundary line extending from the second virtual primary color point at the second apex to the third virtual primary color point at the third apex, and a third virtual boundary line extending from the third virtual primary color point at the third apex to the first virtual primary color point at the first apex.

4. The electronic display of claim 3, wherein the boundary of the virtual color space is triangular.

5. The electronic display of claim 4, wherein the boundary of the virtual color space consists of the first apex at the first virtual primary color point, the second apex at the second virtual primary color point, the third apex at the third virtual primary color point, the first virtual boundary line, the second virtual boundary line, and the third virtual boundary line.

6. The electronic display of claim 2, wherein the one or more derivative light-emitting elements comprises a first derivative light-emitting element configured to emit a first derivative color located at a first derivative color point on the color space chromaticity diagram.

7. The electronic display of claim 6, wherein the first derivative color point is located proximate to the first physical primary color point on the color space chromaticity diagram.

8. The electronic display of claim 6, wherein the first virtual primary color point is spaced from the first physical primary color point and the first derivative color point, the second virtual primary color point is located at the second physical primary color point, and the third virtual primary color point is located at the third physical primary color point.

9. The electronic display of claim 6, wherein the one or more derivative light-emitting elements consists of the first derivative light-emitting element configured to emit the first derivative color located at the first derivative color point.

10. The electronic display of claim 6, wherein the one or more derivative light-emitting elements further comprises a second derivative light-emitting element configured to emit a second derivative color located at a second derivative color point on the color space chromaticity diagram.

11. The electronic display of claim 10, wherein the second derivative color point is located proximate to the second physical primary color point.

12. The electronic display of claim 10, wherein the first virtual primary color point is spaced from the first physical primary color point and the first derivative color point, the second virtual primary color point is spaced from the second physical primary color point and the second derivative color point, and the third virtual primary color point is located at the third physical primary color point.

13. The electronic display of claim 10, wherein the one or more derivative light-emitting elements consists of the first derivative light-emitting element configured to emit the first derivative color located at the first derivative color point and the second derivative light-emitting element configured to emit the second derivative color located at the second derivative color point.

14. The electronic display of claim 10, wherein the one or more derivative light-emitting elements further comprises a third derivative light-emitting element configured to emit a third derivative color located at a third derivative color point on the color space chromaticity diagram.

15. The electronic display of claim 14, wherein the first derivative color point is located proximate to the first physical primary color point, the second derivative color point is located proximate to the second physical primary color point, and the third derivative color point is located proximate to the third physical primary color point.

16. The electronic display of claim 14, wherein the first virtual primary color point is spaced from the first physical primary color point and the first derivative color point, the second virtual primary color point is spaced from the second physical primary color point and the second derivative color point, and the third virtual primary color point is spaced from the third physical primary color point and the third derivative color point.

17. The electronic display of claim 14, wherein the first physical primary color point and the second derivative color point are located on the first virtual boundary line, the second physical primary color point and the third derivative color point are located on the second virtual boundary line, and the third physical primary color point and the first derivative color point are located on the third virtual boundary line.

18. The electronic display of claim 14, wherein the one or more derivative light-emitting elements consists of the first derivative light-emitting element configured to emit the first derivative color located at the first derivative color point, the second derivative light-emitting element configured to emit the second derivative color located at the second derivative color point, and the third derivative light-emitting element configured to emit the third derivative color located at the third derivative color point.

19. The electronic display of claim 1, further comprising a computer processor configured to convert a color value defined based the first virtual primary color point, the second virtual primary color point, and the third virtual primary color point to corresponding outputs for the first primary light-emitting element, the second primary light-emitting element, the third primary light-emitting element, and each of the one or more derivative light-emitting elements.

20. The electronic display of claim 1, wherein the color space chromaticity diagram is an XYZ chromaticity diagram adopted by International Commission on Illumination in 1931.
